(19) United States
(12) Patent Application Publication
(10) Pub. No.: US 2025/0266788 A1
(43) Pub. Date: Aug. 21, 2025

(54) DEVICE FOR GENERATING ELECTRICITY

(71) Applicant: CLEARVUE TECHNOLOGIES LTD, West Perth (AU)

(72) Inventors: Jamie LYFORD, West Perth (AU); Victor ROSENBERG, West Perth (AU); Steven COONEN, Grass Valley, CA (US)

(73) Assignee: CLEARVUE TECHNOLOGIES LTD, West Perth (AU)

(21) Appl. No.: 19/198,993

(22) Filed: May 5, 2025

Related U.S. Application Data
(63) Continuation of application No. 17/754,383, filed on Mar. 31, 2022, now abandoned.

(30) Foreign Application Priority Data
Oct. 1, 2019 (AU) 2019903698
Nov. 12, 2019 (AU) 2019904261

(51) Int. Cl. H02S 20/26; E06B 3/67; E06B 7/28; E06B 9/24; H02S 40/22

(52) U.S. Cl. CPC H02S 20/26; E06B 3/6715; E06B 7/28; E06B 9/24; H02S 40/22; E06B 2009/2417; E06B 2009/2476

(57) ABSTRACT

A device for window of a building or structure including a panel having an area that is transparent for at least a portion of visible light and having opposite first and second major surfaces. The first major surface is a light receiving surface. The device further includes at least one series of solar cells, each having a light receiving surface which faces the second major surface of the panel and is directly or indirectly bonded to the panel at the second major surface in a manner such that light can be received by the light receiving surfaces of the solar cells without propagating through a gap between the panel and the light receiving surfaces. The at least one series of solar cells is positioned at and along an edge of the panel and between the edge and the area that is transparent for at least a portion of visible light.

### CROSS REFERENCE TO RELATED APPLICATIONS

This application is a continuation of U.S. application Ser. No. 17/754,383 filed on Mar. 31, 2022, and entitled Device For Generating Electricity, which is a national stage filing under Section 371 of International Application No. PCT/AU2020/051051, filed on Oct. 1, 2020, and published on Apr. 8, 2021 as WO 2021/062477, which claims priority to Australian Application No. AU 2019903698, filed Oct. 1, 2019, and also claims priority to Australian Application No. AU 2019904261, filed Nov. 12, 2019. The entire contents of each application are incorporated herein by reference in their entireties.

### FIELD OF THE INVENTION

The present disclosure relates to a device for generating electricity and relates particularly, though not exclusively, to a panel, such a panel for a window comprising solar cells.

### BACKGROUND OF THE INVENTION

Buildings such as office towers, high-rise housings and hotels use large amounts of exterior window panelling and/or facades which incorporate glass panelling.

Such glass panelling receives large amounts of sunlight, which results in heating of interior spaces requiring the use of air conditioners. A large amount of energy is globally used to operate air conditioners.

PCT international applications numbers PCT/AU2012/000778, PCT/AU2012/000787 and PCT/AU2014/000814 (owned by the present applicant) disclose a spectrally selective panel that may be used as a windowpane and that is transmissive for visible light, but has solar cell that absorb light, such as infrared radiation, to generate electricity.

The present invention provides further improvement.

### SUMMARY OF THE INVENTION

The present invention provides in a first aspect a device for window of a building or structure, the device comprising:
a panel having an area that is transparent for at least a portion of visible light and having opposite first and second major surfaces, the first major surface being a light receiving surface of the panel; and
at least one series of solar cells, each solar cell having a light receiving surface which faces the second major surface of the panel and is the directly or indirectly bonded to the panel at the second major surface in a manner such that light can be received by the light receiving surfaces of the solar cells without propagating through a gap between the panel and the light receiving surfaces of the solar cells;
wherein the at least one series of solar cells is positioned at and along an edge of the panel and between the edge and the area that is transparent for at least a portion of visible light, and
wherein solar cells are only positioned at and along one or more edges of the panel and not in the area that is transparent for at least a portion of visible light.

As the gap, such as an airgap, between the panel and the solar cells is avoided, intensity losses of light propagating from the panel into the solar cell are reduced.

The panel may be a panel of a window of a building or a vehicle and the device may further comprise a frame structure for supporting the panel. In one embodiment the device is provided in the form of a window unit for a building, such as an integrated glass unit.

The solar cells of the at least one series of solar cells may be directly or indirectly bonded to the panel using an adhesive. In one embodiment the adhesive is transmissive for visible light and may have a refractive index that at least approximates that of the panel material, which may for example be glass or a suitable polymeric material. Alternatively, the solar cells may have an outer layer of a polymeric material, such as Polyvinyl butyral (PVB) or ethylene-vinyl acetate (EVA) or another suitable material. The solar cells may in this embodiment be directly bonded to the second major surface of the panel. For example, if the solar cells comprise a layer of EVA or another suitable material, the PVB, EVA or the other suitable material may be slightly softened and then adhered to the second major surface of the panel typically without an additional adhesive (by using the PVB, EVA or the other material as an adhesive).

The solar cells of the at least one series of solar cells may be positioned parallel to the panel. Adjacent solar cells may be in an at least nearly abutting relationship with each other. Alternatively, each solar cell may have opposite major surfaces having opposite electrical polarities and each solar cell may overlap another one of the solar cells such that a series of “shingled′ solar cells is formed.

The device may comprise a plurality of the series of solar cells and which may be positioned around (and may entirely surround) the area that is transparent for at least a portion of visible light. The plurality of the series of solar cells may be positioned at edges of the panel such that the panel is largely transparent for at least a portion of visible light and the area that is transparent for at least a portion of visible light is a central area and at 5, 10, 15, 20, 50, 100 or even 500× larger than an area of the panel at which the series of the solar cells are positioned.

The panel may have four edges and at least one of the series of solar cells may be positioned at each edge of the panel.

The area that is transparent for at least a portion of visible light may be transmissive for at least 60%, 70%, 80%, 90% or even at least 95% or visible light incident of the receiving surface at normal incidence.

The panel may be a first panel and the device may comprise a second panel that may be positioned substantially parallel the first panel in a manner such that light received by the light receiving surface of the first panel initially propagates through the first panel before being received by the second panel. The second panel may also have an area that is transparent for at least a portion of visible light and having opposite first and second major surfaces, the first major surface being a light receiving surface of the second panel.

In this embodiment each solar cell may have a rear surface that is directly or indirectly bonded to the second panel whereby each solar cell may be directly or indirectly bonded to both the first and the second panels and the solar cells are sandwiched between the first and second panels. In this embodiment both the front and also the rear surfaces of the device are surfaces of the first or second panel (which may be glass panels), which has the advantage of protecting the solar cells and also has the advantage of providing reliable (vacuum) sealing surfaces for window application.

The at least one series of solar cells may be at least one series of first solar cells and the device may further comprise at least one series of second solar cells positioned at the second panel. Each solar cell of the series of second solar cells may have a light receiving surface which faces the second panel and is directly or indirectly bonded to the second panel at the second major surface in a manner such that light can be received by the light receiving surface of the second solar cells without propagating through a gap between the second panel and the light receiving surface of the solar cells;

wherein the at least one series of solar cells is positioned at and along an edge of the second panel, and between the edge and the area that is transparent for at least a portion of visible light, and wherein solar cells are only positioned along and in the proximity of one or more edge of the second panel and not in the area that is transparent for at least a portion of visible light.

The second panel may have four edges and may comprise at least one of the series of second solar cells positioned at each edge of the second panel.

The area that is transparent for at least a portion of visible light may be transmissive for at least 60%, 70%, 80%, 90% or even at least 95% or visible light incident on the second panel.

The second panel may further comprise a diffractive element and/or luminescent material in order to facilitate redirection of incident infrared light to edges of the second panel.

Further, the device may comprise at least one series of third solar cells that is positioned at at least one edge surface of the second panel and oriented substantially perpendicular to a major surface of the second panel whereby the at least one series of third solar cells is positioned substantially perpendicular to the series of first solar cell at the first panel and the series of second solar cells at the second panel. The series of third solar cells is positioned to receive at least a portion of light redirected by the diffractive element and/or the luminescent material. The deflection of infrared radiation by the diffractive element has the further advantage that transmission of infrared radiation into buildings (when the panel is used as a window pane) can be reduced, which consequently reduces overheating of spaces within the building and can reduce costs for air conditioning.

The solar cells may be silicon-based solar cells, but may alternatively also be based on any other suitable material, such CIGS or CIS, GaAs, CdS or CdTe.

In one specific embodiment the solar cells of the series of first solar cells and the series of second solar cells are silicon-based and the solar cells of the series of third solar cells are CIS-or CIGS-based.

The invention will be more fully understood from the following description of specific embodiments of the invention. The description is provided with reference to the accompanying drawings.

### BRIEF DESCRIPTION OF THE DRAWINGS

FIG. 1 is a schematic top view of a device for generating electricity in accordance with an embodiment of the present invention; and

FIGS. 2 and 3 are schematic cross-sectional representation of a portion of the device in accordance with an embodiment of the present invention.

### DETAILED DESCRIPTION OF EMBODIMENTS

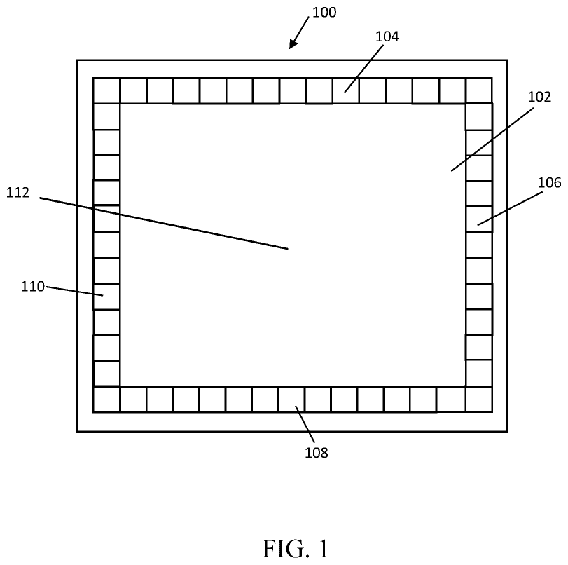

Referring initially to FIG. 1, there is shown a schematic top view of a device for generating electricity 100 in accordance with an embodiment of the present invention. The device 100 comprises a panel 102 and in this embodiment four series of solar cells 104, 106, 108, 110 are positioned at respective edges of the panel 102. The four series of solar cells 104, 106, 108, 110 face a light receiving surface of the panel and together surround an area of the panel that is at least largely transmissive for light. The panel 102 may for example form a panel of a window of a building or another structure and the four series of solar cells 104, 106, 108, 110 may be positioned at a frame structure that supports the panel 102 and one or more other panels to for a window unit.

The panel 102 is transmissive for at least 70% of incident visible light (limited by the transmissivity of the panel material, such as glass). The solar cells are only positioned at edges of the panel 102 such that only at edges of the panel 102 the transmission of incident light is obstructed by the solar cells.

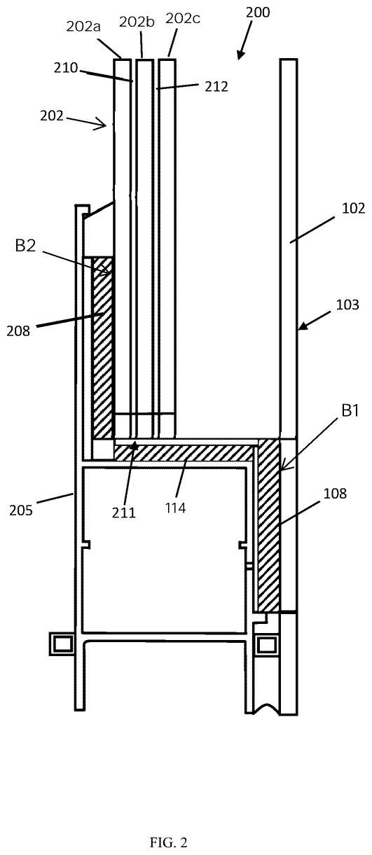

The solar cells of the series 104, 106, 108, 110 each have light receiving surfaces facing the panel 100 and are adhered (indicated in FIG. 2 at “B1”) to the panel 102 such that no air gap is present between the solar cells and the panel 102. In this example the solar cells 112 comprise outer ETA layers. Prior to adhering the solar cells 112 to the panel 102, the ETA is slightly softened (by the careful application of heat) and then the solar cells 112 are pressed against the panel 102. Once the softened ETA has hardened again, the solar cells are adhered B1 to the panel 102 without the need of an additional adhesive.

The panel 102 may have any shape, but in one specific embodiment is rectangular and may be square. The panel 102 may be formed from suitable glass or polymeric materials.

The solar cells 104, 106, 108, 110 are in this embodiment arranged in an overlapping relationship and electrically coupled using a conductive adhesive. The solar cells 112, have opposite major surfaces and which have different polarities and are oriented such that only surfaces of the same polarities face the panel 102. The conductive adhesive couples a back face of one of the solar cells 112 with a front face of an adjacent solar cell 112. Consequently, the solar cells of the series of solar cells are electrically series connected.

Alternatively, the solar cells may be arranged in an abutting relationship.

Turning now to FIG. 2, there is shown a cross-sectional view of a portion of a window unit 200 in accordance with an embodiment of the present invention. The window unit 200 comprises the panel 102 with the series of (shingled) solar first cells 104, 106, 108 and 110, which are encapsulated by a layer of ETA 109. The panel 102 has a light receiving surface 103. In this embodiment the panel 102 is a first panel and the window unit 200 also comprises a second panel 202, which is positioned parallel, and spaced apart from, the first panel 102. The second panel 202 has series of solar cells 208 adhered to it in the same manner as illustrated above for the first panel 102 and with reference to FIG. 1. In this embodiment the panels 102 and 202 are rectangular and each comprise four series of solar cells that are adhered at edge portions of the panels 102, 202 and positioned as illustrated in FIG. 1.

Similar to the panel 102 illustrated in FIG. 1, the second panel 202 is transmissive for at least 70% of incident visible light (limited by the transmissivity of the panel material, such as glass). The solar cells are only positioned at edges of the panel 202 such that only at edges of the panel 202 the transmission of incident light is obstructed by the solar cells.

The window unit 200 also comprises a frame structure 205 that is arranged to hold the panels 102 and 202 and the series of solar cells in position.

The panels 102 and 202 comprise in this embodiment respective panes of glass that are each largely transmissive for visible light. In an embodiment the glass panes that form the panels 102 and 202 are formed of low iron ultra-clear glass pane, with the panel 202 additionally having a low-E coating.

In the embodiment shown in FIG. 2 the panel 202 is a laminate structure having three sub-panes 202a, 202b and 202c. The sub-pane 202a is formed of low iron ultra-clear glass having a thickness of 4 mm, and second and third panes 202b and 202c are each formed from ultra-clear glass having a thickness of 4 mm. The sub-panes 202a, 202b and 202c mate with each other to form a stack of the sub-panes substantially parallel to one another. Disbursed between panes 202a and 202b is an interlayer 210 of polyvinyl butyral (PVB). A PVB interlayer 212 is also located between sub-pane 202b and 202c, but PVB interlayer 212 also includes a light scattering element. In this embodiment the light scattering element comprises a luminescent scattering powder embedded in the PVB, which also an epoxy that provides adhesive. The panel 202 also includes a diffraction grating that is arranged to facilitate redirection of light towards edge region of the panel 202 (i.e. towards the frame 205) and guiding of the light by total internal reflection.

It should be appreciated that the panel 202 could have any number of panes with any number of interlayers. In some embodiments the panel 202 may comprise a single piece of optically transmissive material such as glass.

The panel 202 has an edge 211 that has a plane which is transverse to the light receiving surface 103. In the embodiment of FIG. 2, the angle between the edge 211 and the light receiving surface 103 is 90°.

The window unit 200 also has series of third solar cells 114. The series of third solar cells 114 face the edge 211 and a cavity between the first panel 102 and the second panel 202. The series of third solar cells 114 substantially surround the second panel 202 and are positioned to receive light that is redirected by the scattering material and/or the diffractive element (not shown) to the edges (such as edge 211) of the second panel 202. Further, the series of third solar cells 114 also receives light at an area which faces the cavity between the first panel 102 and the second panel 202.

In the present embodiment, the series of first and second solar cells 104, 106, 108, 110, 208 (adhered to sub-pane 202a as shown in FIG. 2 at “B2”) may be silicon-based solar cells, but can alternatively also be based on any other suitable material such CdS, CdTe, GaAs, CIS or CIGS. The series of third solar cells 114 may be CIS or CIGS-based, but may alternatively also be based on any other suitable material such SI, CdS, CdTe, or GaAs.

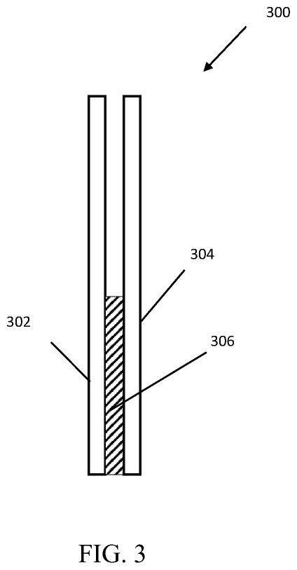

FIG. 3 shows a device for generating electricity in accordance with a further embodiment of the present invention. FIG. 3 shows the device 300 having a first panel 302 and a second panel 304. The first and second panels 302, 304 are transmissive for at least 70% of incident visible light (limited by the transmissivity of the panel material, such as glass).

The device 300 comprises solar cells 306 which each have a light receiving surface facing the panel 302 and adhered to the panel 302 such that no air gap is present between the solar cells 306 and the first panel 302. Further, the solar cells 306 each have a rear surface facing the panel 304 and adhered to the panel 304. In this example the solar cells 306 comprise outer ethylene-vinyl acetate (EVA) or Polyvinyl butyral (PVB) layers at the front surfaces. A sheet of excluded-volume-branched-polymers (EVB), Polyvinyl butyral (PVB) or Ethylene tetrafluoroethylene (ETFE) is placed between the panels 302 and 304 such that the sheet is also positioned between the rear surfaces of the solar cells 306 and panel 304. Prior to adhering the solar cells 306 to the panels 302, 304 (and the panels 302, 304 to each other) the ETA, EVB or ETFE is slightly softened (by the careful application of heat) and then the panel 302, 304 are pressed together such that the solar cells 306 are positioned between the panels 302, 304. Once the softened ETA, EVB or ETFE has hardened again, the solar cells are sandwiched between, and adhered to, the panels 302, 304 without the need of an additional adhesive whereby a laminated structure is formed. The panels 302, 304 protect the solar cells 306 and also provide reliable sealing surfaces at both front and rear sides of the device, which is advantageous for window applications.

Whilst a number of specific embodiments have been described, it should be appreciated that the disclosed unit 200 maybe embodied in many other forms. For example, the unit 200 may not necessarily be rectangular, but may alternatively have any other suitable shape (such as for example round or rounded). Further, the panel 202 may comprise any suitable number of sub-panels. Further, the window unit may comprise a third panel such that a triple glazing unit is formed.

Any discussion of the background art throughout this specification should in no way be considered as an admission that such background art is prior art, nor that such background art is widely known or forms part of the common general knowledge in the field in Australia or worldwide.

1. A device for window of a building or structure, the device comprising:
a panel having an area that is transparent for at least a portion of visible light and having opposite first and second major surfaces, the first major surface being a light receiving surface of the panel; and
at least one series of solar cells, each solar cell having a light receiving surface which faces the second major surface of the panel and is the directly or indirectly bonded to the panel at the second major surface in a manner such that light can be received by the light receiving surface of the solar cell without propagating through a gap between the panel and the light receiving surface of the solar cell;
wherein the at least one series of solar cells is positioned at and along an edge of the panel and between the edge and the area that is transparent for at least a portion of visible light, and
wherein solar cells are only positioned at and along and one or more edges of the panel and not in the area that is transparent for at least a portion of visible light.

2. The device of claim 1 wherein the panel is a panel of a window of a building or a vehicle and the device further comprises a frame structure for supporting the panel.

3. The device of claim 2 wherein the device is provided in the form of a window unit for a building, such as an integrated glass unit.

4. The device of claim 1 wherein the solar cells of the at least one series of solar cells are directly or indirectly bonded to the panel using an adhesive.

5. The device of claim 4 wherein the adhesive has a refractive index that at least approximates that of the panel material.

6. The device of claim 1 wherein the solar cells have an outer layer of a polymeric material.

7. The device of claim 6 wherein the polymeric material is ethylene-vinyl acetate (EVA) or Polyvinyl butyral (PVB).

8. The device of claim 1 wherein the solar cells are directly bonded to the second major surface of the panel.

9. The device of claim 7 wherein the EVA or the other suitable material are slightly softened and then adhered directly to the second major surface of the panel without an additional adhesive.

10. The device of claim 1 wherein the device comprises a plurality of the series of solar cells and which are positioned around (and may entirely surround) the area that is transparent for at least a portion of visible light, and wherein the plurality of the series of solar cells are positioned at edges of the panel such that the panel is largely transparent for at least a portion of visible light and the area that is transparent for at least a portion of visible light is a central area and at 5, 10, 15, 20, 50, 100 or even 500× larger than an area of the panel at which the series of the solar cells are positioned.

11. The device of claim 1 wherein the area that is transparent for at least a portion of visible light is transmissive for at least 60%, 70%, 80%, 90% or even at least 95% or visible light incident of the receiving surface at normal incidence.

12. The device of claim 1 wherein the panel is a first panel and the device comprises a second panel that is positioned substantially parallel to the first panel in a manner such that light received by the light receiving surface of the first panel initially propagates through the first panel before being received by the second panel, wherein the second panel also has an area that is transparent for at least a portion of visible light and having opposite first and second major surfaces, the first major surface being a light receiving surface of the second panel.

13. The device of claim 12 wherein each solar cell has a rear surface that is directly or indirectly bonded to the second panel such that each solar is sandwiched between the first and second panel and each solar cell is directly or indirectly bonded to both the first and the second panel.

14. The device of claim 12 wherein the at least one series of solar cells is at least one series of first solar cells and the device further comprises at least one series of second solar cells positioned at the second panel; wherein each solar cell of the series of second solar cells has a light receiving surface which faces the second panel and is directly or indirectly bonded to the second panel at the second major surface in a manner such that light can be received by the light receiving surface of the solar cell without propagating through a gap between the second panel and the light receiving surface of the solar cell;
wherein the at least one series of solar cells is positioned at and along an edge of the second panel, and between the edge and the area that is transparent for at least a portion of visible light, and wherein solar cells are only positioned along and in the proximity of one or more edge of the second panel and not in the area that is transparent for at least a portion of visible light.

15. The device of claim 12 wherein the area that is transparent for at least a portion of visible light may be transmissive for at least 60%, 70%, 80%, 90% or even at least 95% or visible light incident on the second panel.

16. The device of claim 13 wherein the second panel further comprises a diffractive element and/or luminescent material in order to facilitate redirection of incident infrared light to edges of the second panel.

17. The device of claim 13 wherein the device comprises at least one series of third solar cells that is positioned at at least one edge surface of the second panel and oriented substantially perpendicular to a major surface of the second panel whereby the at least one series of third solar cells is positioned substantially perpendicular to the series of first solar cell at the first panel and the series of second solar cells at the second panel, wherein the series of third solar cells is positioned to receive at least a portion light redirected by the diffractive element and/or the luminescent material.

18. The device of claim 12 wherein the solar cells of the series of first solar cells and the series of second solar cells are silicon-based and the solar cells of the series of third solar cells are CIS-or CIGS-based.
